(19) United States
(12) Patent Application Publication
(10) Pub. No.: US 2022/0217861 A1
(43) Pub. Date: Jul. 7, 2022

(54) COMPUTING CENTRE MODULE AND METHOD

(71) Applicant: Cloud & Heat Technologies GmbH, Dresden (DE)

(72) Inventor: Andreas Strech, Dresden (DE)

(21) Appl. No.: 17/595,956

(22) PCT Filed: Jun. 3, 2020
(86) PCT No.: PCT/EP2020/065320

§ 371 Date: Nov. 30, 2021

(30) Foreign Application Priority Data
Jun. 5, 2019 (DE) 10 2019 115 126.0

(51) Int. Cl. H05K 5/02; H05K 5/03

(52) U.S. Cl. CPC H05K 5/0286; H05K 5/03; H05K 5/0247

(57) ABSTRACT

A computing center module (151), comprising: a plurality of containers (102), each container (102) having a plurality of side walls (102s) that are substantially (e.g. on 3 sides) fully openable with two fixed walls (102z) behind them on the two short ends having standardized feed interfaces (412) for all media and containing at least one entrance door (712t), thus leaving the container (102) unchanged; a computing device (104) within the container (102), the computing device (104) having a plurality of processors (104p); an improved reliability power supply infrastructure (106) within the container (102) for supplying electrical power to the computing device (104); wherein the power supply infrastructure of each container (102) of the computing center module (151) or the entire container (102) is individually pre-certified with respect to a reliability of the computing device (104).

Various embodiments relate to a computing center module and method.

To accommodate continued growth, container computing centers have become popular in recent years, where the individual components of a computing center are arranged in a transportable container. Such containers may be prefabricated and preinstalled by manufacturers ex works, thus enabling efficient modular construction of larger computing centers at any given location.

Traditionally, the container computing center is built on site, assembled, and its components are subsequently wired together. When the components are assembled and wired, attention is often paid to the reliability of the entire container computing center, as reliability may be critical to a variety of services that the container computing center may provide. Therefore, testing of actual reliability is not performed until the container computing center as a whole is fully constructed and operational. The result of the test is subsequently classified and certified to the container computing center (also referred to as computing center certification). However, changes to the container computing center may require a new computing center certification under certain circumstances.

According to various embodiments, it has been illustratively recognized that computing center certification enables logistically independent components of the container computing center to be arranged within a container and to be individually pre-certified for each container (also referred to as pre-certification). In other words, the container containing the component may be individually reliability tested in terms of its physical structure and thus receive pre-certification before the computing center is fully constructed or before the container is even transported to its final location.

According to various embodiments, a plurality of individually pre-certified containers are provided that are assembled into a computing center module without impacting their pre-certification. Thus, it is possible to put the individually pre-certified containers into operation as quickly as possible and with a high degree of reliability. For example, the use of the individually pre-certified containers may accelerate and/or simplify (e.g., make cheaper) the construction of the computing center or its computing center certification and thus meet the increasing demand for shortened times from planning to commissioning.

Different availability classes 1 to 4 require certain arrangements and duplications (redundancies) of typical components and supply paths of the trades electricity, network or Internet for the media supply and cooling as waste heat disposal. In addition, there are also structural requirements (e.g., requirements for resistance class against burglary for doors or fire and smoke protection requirements, space requirements for maintenance and installation) for each availability class. The availability classes are assigned average expected availabilities of the IT components (information technology components) in percent per operating year.

With a computing center or development for availability class 3, availability classes 2 or 1 may also be met by omitting or not using components.

It becomes clear that cost advantages may be achieved with a development of a flexible module platform that aims for the highest possible availability and that covers as many use cases as possible, and that the idea and the associated intellectual work must be protected from imitation in order to be able to transfer it to series production.

According to various embodiments, a configuration is provided for the computing center module or method that does not provide any internals in the container walls and doors, and provides media supply and removal and air openings and an access and entry door only via a double wall behind the container door at the front end. This is because it provides simplified international transport and burglary protection, but more importantly it also provides a 3-sided scaling option in the x, y and z directions.

Illustratively, each individually pre-certified container is provided such that its coupling to the rest of the computing center does not require any modifications to those components of the container that meet the pre-certification requirements. Thus, each individually pre-certified container may be added to the computing center “as is,” possibly relocated within it, or removed from the computing center (e.g., for replacement) without affecting the computing center's computing center certification. Further, scalability to larger computing centers may be done on a module-by-module basis and international transport of containers may be simplified.

For example, several individually pre-certified containers (e.g., so-called 20 ft containers) of the same design, which are set up symmetrically with respect to each other, may be used to set up a grouping (e.g., with 1.0 megawatt or more), which serves as a computing center module and is optionally horizontally and/or vertically scalable. Instead of two symmetrically configured containers, a larger container (e.g. a so-called 40 ft container) may also be used, which has two symmetrically configured segments.

According to various embodiments, a computing center module may comprise: a plurality of containers, wherein each container comprises a plurality of side walls that are substantially fully openable; a computing device within the container, wherein the computing device comprises a plurality of processors; a power infrastructure within the container for providing electrical power to the computing device; and wherein the power infrastructure of each container of the computing center module is individually pre-certified with respect to reliability of the computing device.

Depicted is:

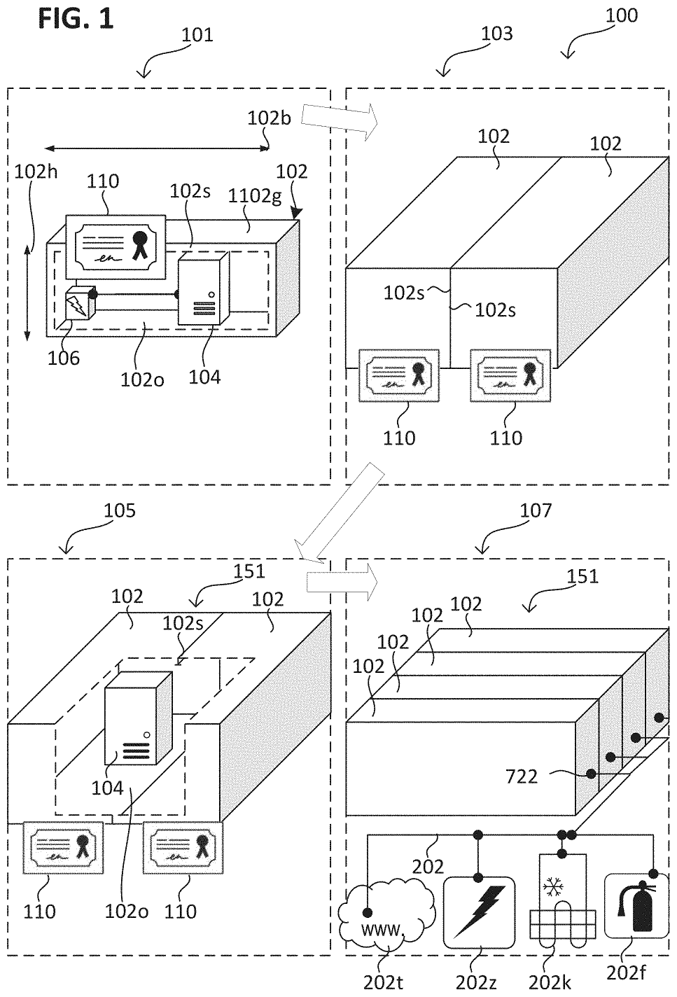

FIG. 1 a process according to various embodiments in a schematic flowchart;

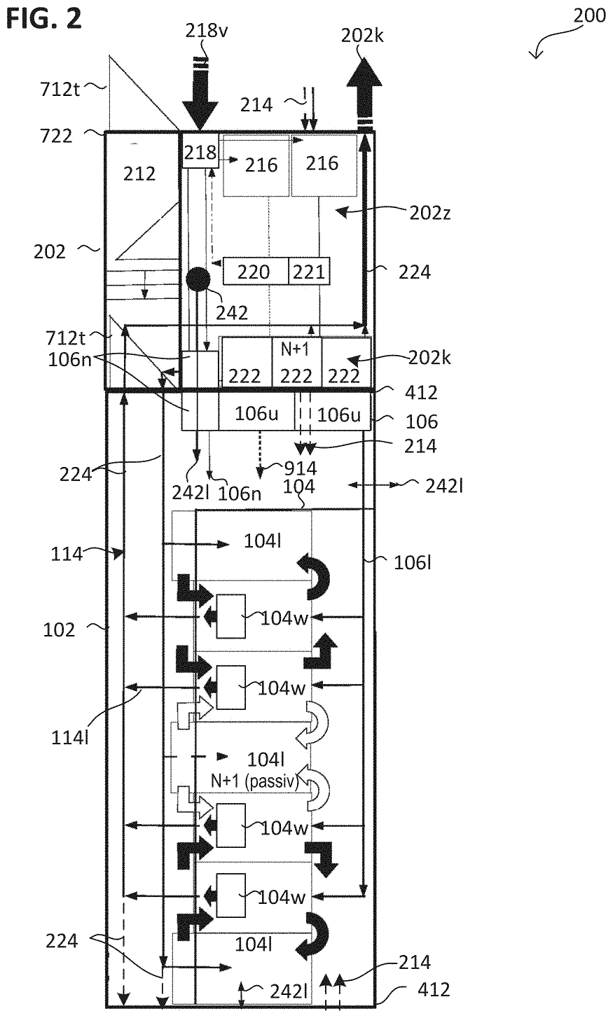

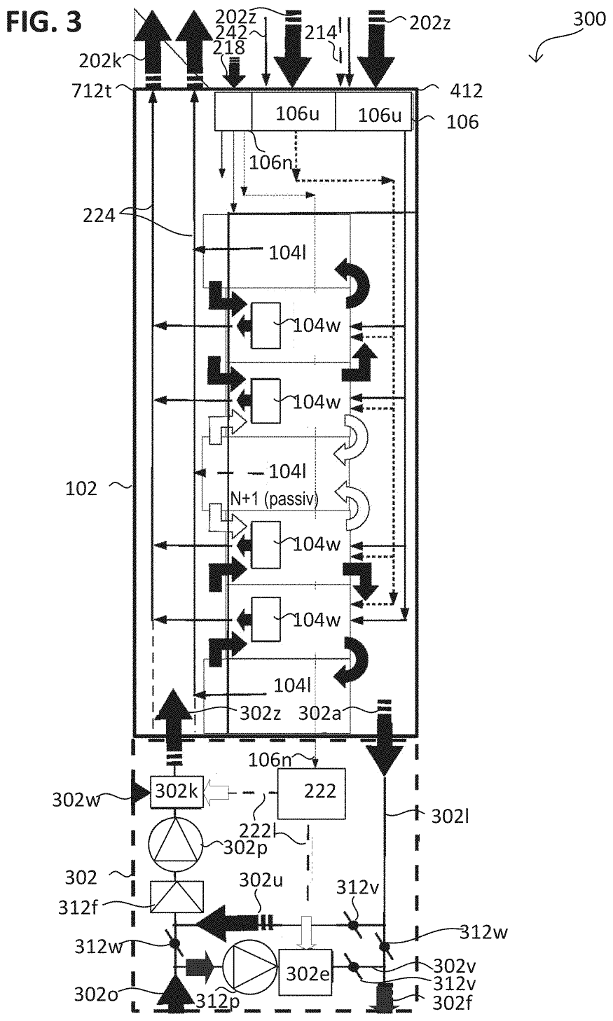

FIGS. 2 and 3 each show a supply chain according to different embodiments in a schematic supply diagram;

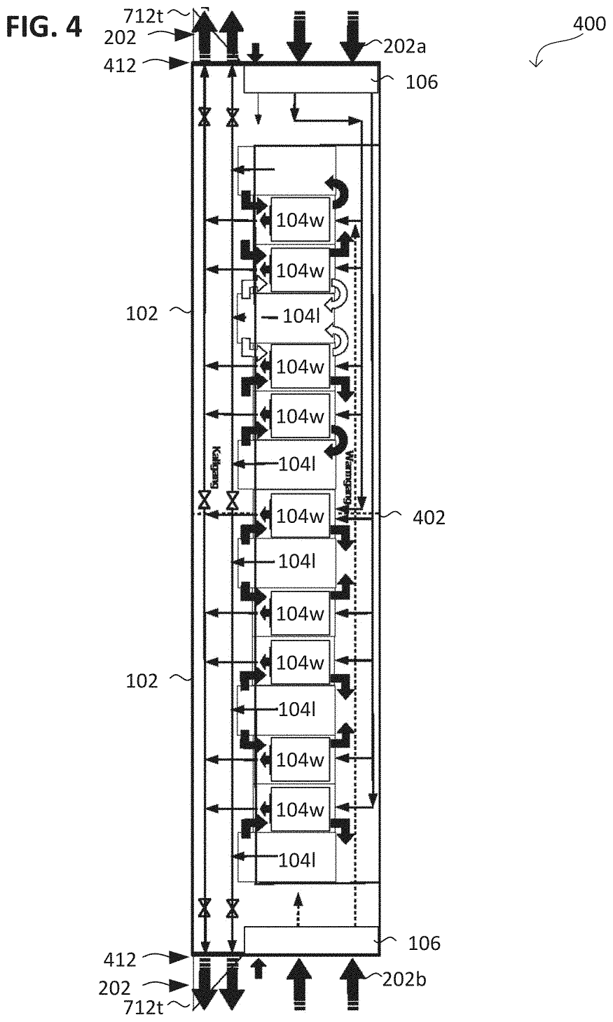

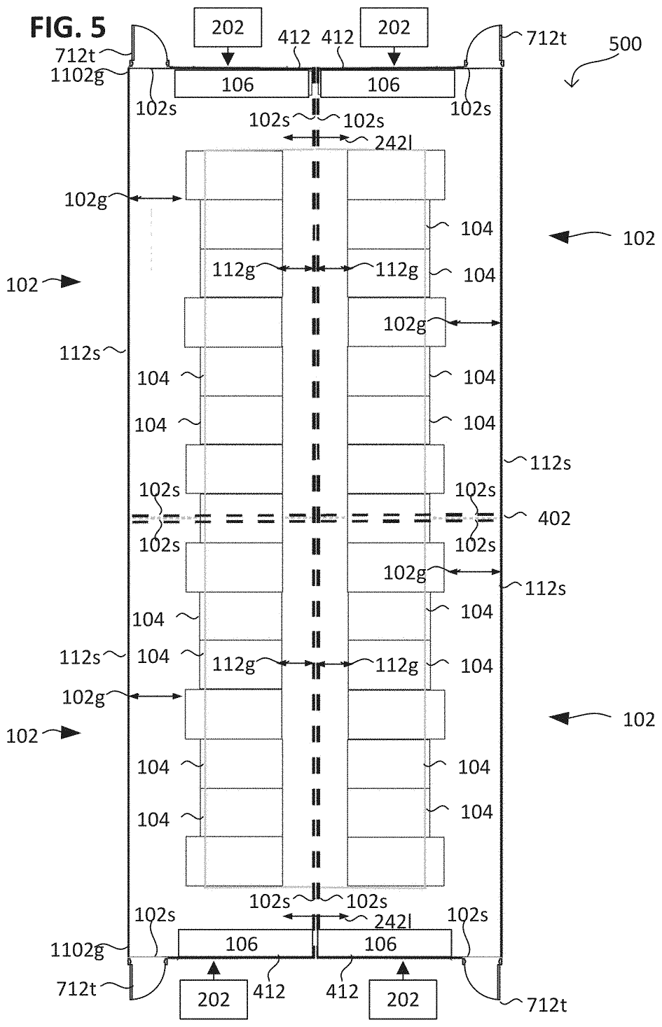

FIGS. 4 and 5, respectively, a computing center module (e.g., a 40 ft computing center module) according to various embodiments in a schematic supply diagram;

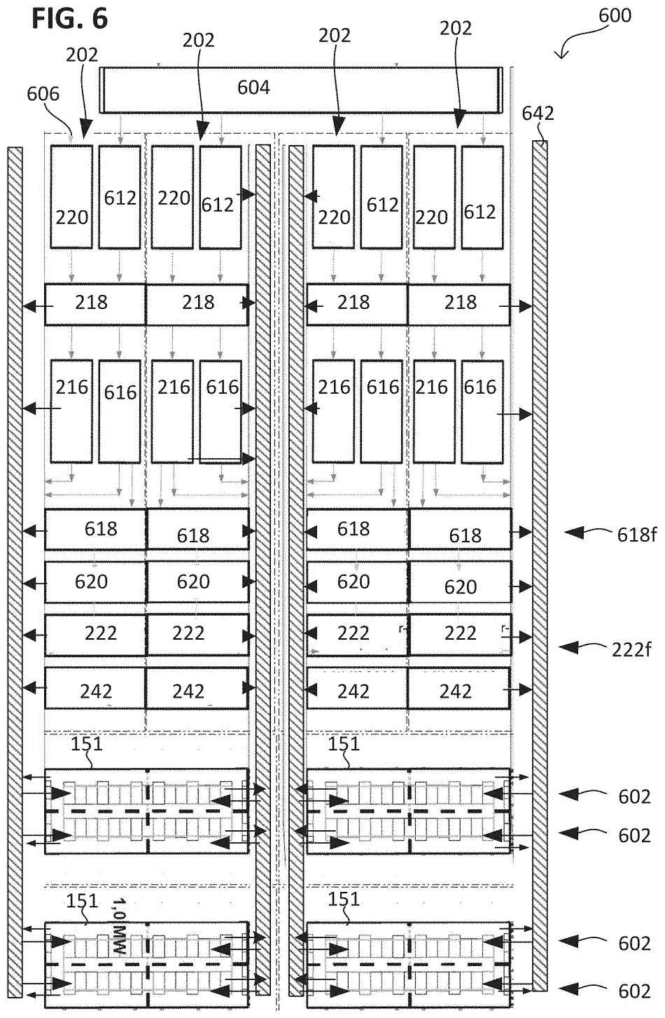

FIG. 6 a computing center according to various embodiments in a schematic supply diagram;

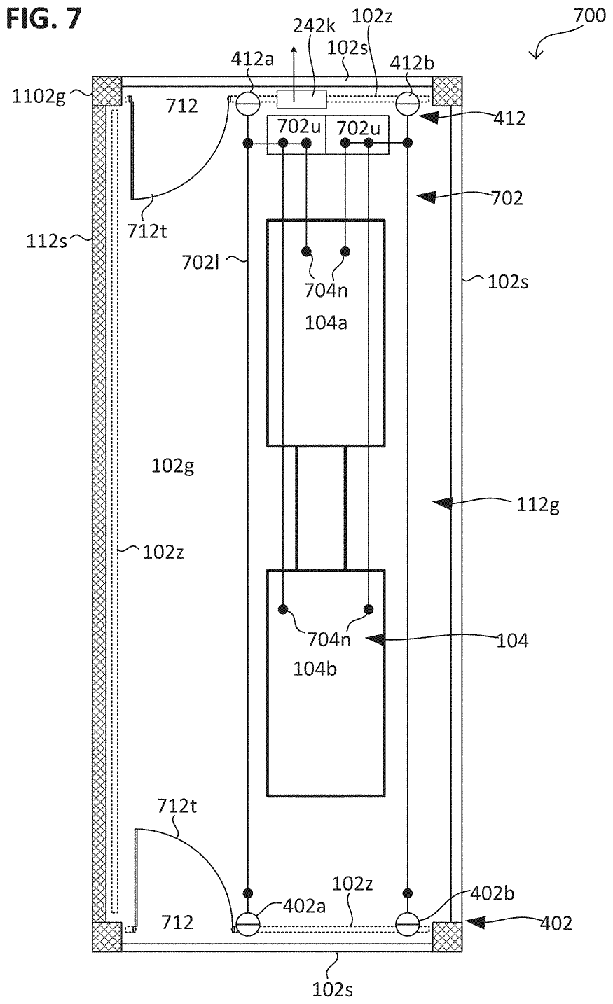

FIG. 7 a pre-certified container according to various embodiments in a schematic assembly diagram;

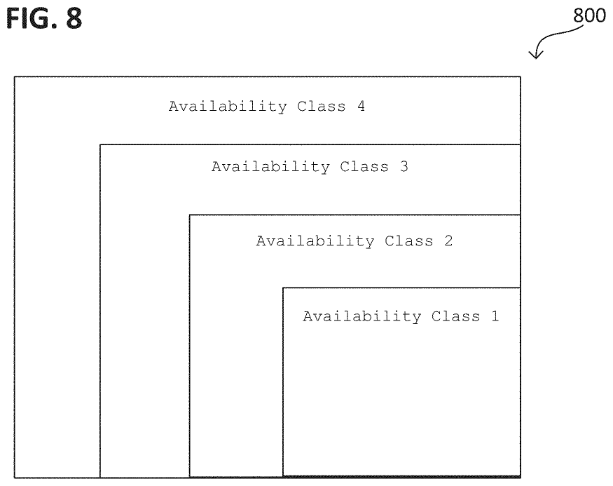

FIG. 8 several availability classes according to different embodiments in a schematic diagram; and

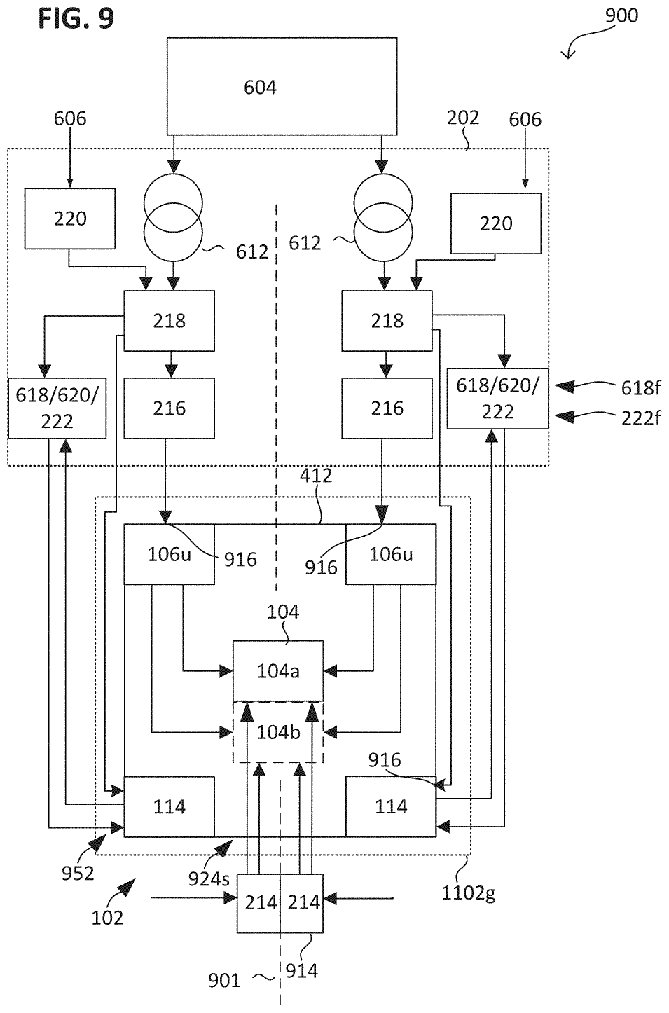

FIGS. 9, 10, and 11 each show a supply chain according to various embodiments in a schematic supply diagram.

In the following detailed description, reference is made to the accompanying drawings which form part thereof and in which are shown, for illustrative purposes, specific embodiments in which the invention may be practiced. In this regard, directional terminology such as “top”, “bottom”, “front”, “rear”, “forwards”, “rearwards”, etc. is used with reference to the orientation of the figure(s) described. Since components of embodiments may be positioned in a number of different orientations, the directional terminology is for illustrative purposes and is not limiting in any way. It is understood that other embodiments may be used and structural or logical changes may be made without departing from the scope of protection of the present invention. It is understood that the features of the various exemplary embodiments described herein may be combined, unless otherwise specifically indicated. Therefore, the following detailed description is not to be construed in a limiting sense, and the scope of protection of the present invention is defined by the appended claims.

In the context of this description, the terms “connected”, “attached” as well as “coupled” are used to describe both a direct and an indirect connection (e.g. ohmic and/or electrically conductive, e.g. an electrically conductive connection), a direct or indirect attachment as well as a direct or indirect coupling. In the figures, identical or similar elements are given identical reference signs where appropriate.

According to various embodiments, the term “coupled” or “coupling” may be understood in the sense of a (e.g. mechanical, hydrostatic, thermal and/or electrical, but also data), e.g. direct or indirect, connection to an interaction chain. For example, multiple coupled elements may interact with each other along the interaction chain (e.g., communicatively) so that a medium (e.g., an information, energy, and/or matter) may be exchanged between them. For example, two coupled elements may exchange an interaction with each other, e.g., a mechanical, hydrostatic, thermal, and/or electrical interaction, but also a data interaction. According to various embodiments, “coupled” may be understood in the sense of a mechanical (e.g., physical or physical) coupling, e.g., by means of a direct physical contact. A coupling may be arranged to transmit a mechanical interaction (e.g., force, torque, etc.).

According to various embodiments, an ISO container (e.g., a 20 ft container) with three openable side walls (also referred to as loose walls), a so-called “3-side door container”, is provided as a transport unit and assembly module. The outer shell of the ISO container may be unchanged (i.e., for example, there are no connections on the outer walls of the container on at least two or three sides), so that it retains its CSC certification (COC—“Convention for Safe Containers”), and is thus internationally transportable and additionally inconspicuous (e.g., does not suggest any conclusions about its contents). This is achieved, for example, by means of several partitions (e.g. inner walls) at the two ends of the container, which are arranged behind the loose walls (e.g. having hinged doors) and carry a security door with access control and also flange connections. For example, two 20 ft containers (20-foot containers) may be joined together at their ends to form a pair of containers of the first type, thus forming a 40-foot (approximately 12.2-meter) long unit. Two 20 ft containers may alternatively or additionally be joined together at their long sides to form a pair of second type containers, thus forming a common center aisle. For example, two pairs of containers of the same type may be joined together in this way to form a space-saving and functional grouping. The containers of each container pair may be arranged mirrored to each other. However, other containers, e.g. 40-ft containers or non-ISO containers, may also be used.

In this way, contiguous computing center modules, e.g., with an electrical power of 1 MW (megawatt) or more, may be provided, having, for example, one or more than one container pair (e.g., of the same type). Optionally, vertical scaling may be achieved by stacking multiple computing center modules.

Various embodiments provide a container that may be equipped, for example, with a computing device (e.g., comprising a computer, server or several processor racks) for the modular construction of a high-performance computing center. One effect of the container form is that a computing center formed from such containers may be expanded in a modular manner, and that, for example, each individual container may be prefabricated ex works by the manufacturer and pre-certified with respect to a reliability of the computing equipment.

One effect of pre-certification is that the containers no longer need to be certified after they have been transported to the computing center site. This makes it possible to put the computing center into operation at the destination more quickly and with less effort.

The or each container (e.g. an ISO container) may, for example, be designed in accordance with ISO Standard 668. This has the effect that, in this regard, transport of the container on ships, railroads and trucks is standardized and thus easily possible. In various embodiments, the container may have an outer length of 13,716 m (45 ft), 12,192 m (40 ft, e.g. as a standard container or sea container), 9,125 m (30 ft), 6,058 m (20 ft, e.g. as a standard container or sea container), 2.991 m (10 ft), 2.438 m (8 ft) or m 1.968 (6 ft), have an outer height of 2.591 m (e.g. as a standard container) or 2.896 m (also referred to as a high-cube container), and an outer width of 2.438 m. For example, a so-called 20 ft container has an outer length of 6,058 m, an outer height of 2,591 m, and an outer width of 2,438 m. A so-called 40 ft container (e.g., 40 ft HC container) has an outer length of 12,192 m, an outer height of 2.896 m, and an outer width of 2,438 m. In one example, the container may have an outer dimension (length×width×height) of 6.058 m×2.438 m×2.896 m. The container may have an inner dimension (length×width×height of the interior) of 5.853 m×2.342 m×2.697 m.

In one embodiment, each substantially fully openable side wall (also referred to as a loose wall) of the container is formed as a multi-winged, foldable or demountable wall. Alternatively or additionally, the loose wall may be configured to be resealable in accordance with ISO standard 668, and/or the container may be indistinguishable from other containers. Thus, in this embodiment, shipping of the container by common carriers and shipping routes may be facilitated in a simple manner by means of trucks, trains, and ships. The or each loose wall may, for example, have wall elements positively connected to a housing of the container or formed therefrom, for example by means of a bearing, connected by means of pins and/or screws.

The computing facility of the or each container includes one or more than one computing unit, for example, arranged to accommodate a plurality of processors and/or storage media in a high-density manner. These may include processors, for example, server processors (CPUs), graphics card processors (GPUs), cryptoprocessors, ASICs, FPGAs, TPU (tensor processing unit), or mining hardware for cryptocurrencies. Storage media may be mechanical hard disk drives (HDDs) or solid state drives (SSDs).

In various embodiments, the container may include a plurality of supply paths with a feed interface configured to supply at least one medium to the container from outside (e.g., by means of coupling an uninterruptible power supply to the feed interface). The medium may be, for example, a temperature-controlled fluid (also referred to as a temperature-control fluid, e.g., cooling water), electrical power, and/or a communication signal (e.g., a network signal). Each supply path may be arranged to functionally interact with the computing device and pass the respective supplied fluid to the computing device. The set of supply and disposal paths within the container may also be referred to herein as infrastructure. Depending on the type of medium (temperature control fluid, electrical power, and/or communications signal), the infrastructure may be referred to as temperature control infrastructure, power supply infrastructure (e.g., power supply infrastructure), or telecommunications infrastructure. For example, the temperature control infrastructure may be arranged to extract thermal energy from the computing device along the supply path. Optionally, supply-critical supply paths or components of the container may be redundant.

Redundancy refers to the presence of functionally identical or comparable resources in a technical system, not all of which are normally required for failure-free operation. Functional redundancy may mean that the supply paths required for operation are designed several times in parallel so that, in the event of failure of one supply path or in the event of maintenance, another supply path ensures uninterrupted operation. Optionally, the mutually redundant supply paths may be spatially separated from each other, e.g. by protective walls and/or spatial separation (e.g. by arranging them on opposite sides of the container) to ensure further safety.

Redundancy of an element used to operate the computing system (e.g., a supply path, a component thereof, or a processor) may be understood herein to mean, for example, that at least one functionally identical or comparable copy of the element is present, and the element and its copy are also set up in such a way that it is possible to switch between them, e.g., without having to interrupt the operation of the computing system. The element and its copy may then be set up to be mutually redundant (also referred to as a mutually redundant pair).

Switching between two mutually redundant elements (e.g. from a first supply path to a supply path that is redundant to it) may be automated, for example, if a malfunction has been detected in the active element. The malfunction may be detected as critical, for example, meaning that it could lead to a failure or partial failure of the computing system. The switching may be performed, for example, by means of a transfer switch, e.g., automated. The pre-certification may require, for example, that the container has an at least partially redundant infrastructure. Alternatively or additionally, e.g., if a container as part of a computing center itself has only some of the typical computing center components (e.g., the transformers, generators, and uninterruptible power supply (UPS) may be centralized and/or located outside of it), the redundant components and supply paths may meet at least some of the requirements for pre-certification (e.g., the container may have two redundant electrical subdistributions and two supply paths), so that pre-certification in principle certifies expected availability, if outside of the container, it also meets the requirements (e.g., Classified as “supports availability class x,” where x=1, 2, 3, or 4).

According to various embodiments, the redundancy may be N+1 redundancy. An N+1 redundancy denotes that the computing device requires a maximum of (e.g., exactly) N supply paths for operation, with at least N+1 supply paths being present in the container. The N+1th supply path may be set up as a passive standby supply path. If one of the N supply paths fails or needs maintenance, its function may be taken over by the N+1th supply path, e.g. without having to interrupt the operation of the computing system. If two of the N supply paths fail, this may result in a failure or partial failure of the computing system (corresponding, for example, to availability class “VK 3” according to DIN EN 50600 or “Tier 3” according to the North American standard of the Uptime Institute). This could be counteracted by using a higher redundancy, e.g. by designing the redundancy as parallel redundancy. In parallel redundancy, at least 2·N supply paths are available, e.g. 2·(N+1) supply paths (corresponding, for example, to availability class “VK 4” according to DIN EN 50600 or “Tier 4” according to the North American standard of the Uptime Institute).

Single-path supply paths without duplication of components, on the other hand, may comply with “VK 1” or “Tier 1”, whereby in addition to the availability classes, further construction requirements (e.g. burglary protection, fire protection, etc.) may be defined in the standards. The computing center module may, for example, be built according to “VK 3” or “Tier 3” standard. A “VK 4” or “Tier 4” standard may be more complex in its fulfillment (e.g. suitable for critical infrastructures, as required for energy supply companies, for example).

FIG. 1 illustrates a method 100 according to various embodiments in a schematic flowchart for handling a plurality of containers 102. Each container 102 may include a housing 1102g, which may include contiguous (e.g., four) side walls, a ceiling, and a floor surrounding an interior of the container. Further, the housing 1102g may include a supporting housing structure (e.g., a frame or framework) to which the plurality of side walls, ceiling, and floor are attached. Of the side walls of the container 102, a plurality of side walls 102s are substantially fully openable (also referred to as loose walls 102s). For example, each loose wall 102s may include at least one (i.e., exactly one or more than one) wall member that may be opened, e.g., by being demountable, movable, or positively supported (e.g., by hinges). The remainder of the loose wall 102s, e.g., the bearing and/or the frame, may be, for example, materially bonded (e.g., welded) to or part of the housing structure. For example, the at least one wall member of each loose wall 102s may be adapted to be opened and/or reclosed in a non-destructive manner. For example, each loose wall 102s may be closed by means of a closure device (e.g., a closure latch or lock).

A substantially fully openable loose wall 102s may be understood to mean that, on the housing side of the container 102 on which the loose wall 102s is disposed, substantially all of the interior of the container may be or may become exposed. For example, the interior of the container 102 may have a height 102h, wherein an opening 102o provided by means of the opened loose wall 102s exposes at least 80% (e.g., 90%) of the height 102h. Alternatively or additionally, the opening 102o may expose at least 80%, (e.g., 90%) of a length 102 b or width of the interior (cf. the interior dimension). The housing structure may optionally segment the opening 102o. For example, at least about 75% (e.g., 80%, 90%, or 95%) of the loose wall 102s relative to an area may comprise the opening 102o, which may be covered by means of the at least one wall member.

The container 102 may have a computing device 104 therein that includes a plurality (e.g., at least 10, at least 100, or at least 1000) of processors. The container 102 may further include, in its interior, an infrastructure 106 for supplying power to the computing device 104 (also referred to as power supply infrastructure or power infrastructure). The power supply infrastructure 106 of each container 102 may be individually pre-certified 110 with respect to reliability of the computing device 104. Optionally, multiple infrastructures or the entire container may be pre-certified as part of a computing center or the container may be pre-certified with additional technology containers. The container with the pre-certified power infrastructure 106 will also be referred to herein as a pre-certified container 102 (FOC or, more simply, a container).

The pre-certification 110 may illustratively represent how high the reliability of the computing device is. For example, the reliability (also referred to as availability) may be greater than 95%, e.g., at least about 98.97%, e.g., at least about 99%, e.g., at least about 99.9% (also referred to as high reliability), e.g., at least about 99.99% (also referred to as very high reliability), e.g., at least about 99.999%. The reliability may be or become classified, i.e., divided into classes (also referred to as availability class), depending on the certification type.

For example, a pre-certification according to DIN EN 50600 (of 2013, e.g. DIN EN 50600-1 of 2013, or DIN EN 50600-2-2 of 2014, or DIN EN 50600-2-3 of 2015) may specify that the reliability of at least about 98.97% is classified as availability class 1, the reliability of at least about 99.9% is classified as availability class 2, the reliability of at least about 99.99% is classified as availability class 3, or the reliability of at least about 99.999% is classified as availability class 4.

For example, a pre-certification according to U.S. Tier Classification (e.g. of 2015) may indicate that reliability of at least about 99.671% is classified as Availability Class 1 (also referred to as Tier 1), reliability of at least about 99.749% is classified as Availability Class 2 (also referred to as Tier 2), reliability of at least about 99.982% is classified as Availability Class 3 (also referred to as Tier 3), or reliability of at least about 99.995% is classified as Availability Class 4 (also referred to as Tier 4).

However, other (e.g. commercial) certification types may also be used, e.g. a Bitcom certification (e.g. according to Bitcom guide 2013) or an InfraOpt certification (from 2017).

Depending on the certification type or availability class, various pre-certification requirements may be met, as described in more detail later, for example, at least N+1 redundancy (or 2·N redundancy) of the power supply infrastructure 106. The pre-certification 110 described herein (with respect to reliability) is to be distinguished from other certification types, in particular those certification types that certify compliance with protection requirements (e.g., CE/ETSI or SEMKO). Such protection requirements may relate, for example, to the protection of the environment, the protection of the user (e.g. his integrity), protection against tampering or data protection and may, for example, be prescribed by law.

The method 100 may have in 101: Providing multiple FOC 102. The providing 101 may optionally comprise in 103: Relocating the plurality of FOC 102, e.g., to land, sea, and/or air. The method 100 may include in 103: Arranging the plurality of FOC 102 relative to each other such that any two FOC 102 of the plurality of FOC 102 are arranged immediately adjacent to each other. For example, they may be arranged with at least two (e.g., face or longitudinal) loose walls 102s facing each other. The method 100 may comprise in 105: Opening one of the plurality of loose walls 102s of the or each FOC 102 facing another FOC 102 of the plurality of FOC 102s. The FOC 102 may be arranged such that when the loose wall 102s is opened, the pre-certification of the FOC 102 (e.g., its power supply infrastructure 106) is maintained. To this end, the or each loose wall 102s of the FOC 102 may be, for example, free of elements that affect the pre-certification, e.g., that affect the fulfillment of the requirement according to the pre-certification. This may illustratively achieve that no certification of the FOC 102 needs to be performed after connecting the interior of the plurality of FOC 102s. This accelerates the deployment of the computing center module 151 having the plurality of FOC 102.

The or each FOC 102 may optionally include a temperature control infrastructure (also referred to as a temperature control infrastructure) and/or a telecommunications infrastructure (also referred to as a telecommunications infrastructure). Optionally, the telecommunications infrastructure (e.g., a network infrastructure) and/or temperature control infrastructure of each FOC 102 may also be individually pre-certified 110 with respect to the reliability of the computing device 104, or the entire container 102 may be pre-certified 110 along with its one or more than one (e.g., different) infrastructures.

The FOCs 102 arranged adjacent to each other may provide a computing center module 151. Multiple computing center modules 151 may be coupled together to form a computing center, for example, by coupling each FOC 102 to an external supply module assembly 202.

The method 100 may comprise in 107: Coupling the plurality of FOCs 102 to each other and/or to at least one external supply module assembly 202. The or each supply module assembly 202 may include one or more than one additional module, e.g., optionally a telecommunications module 202t, a power module 202z, a temperature control module 202k (e.g., cooling module), and/or a gas extinguishing module 202f.

For example, multiple supply module assemblies 202 may be provided, each supply module assembly 202 directly coupled to exactly one FOC 102 or exactly one container pair. Optionally, multiple supply module assembly 202 may be coupled to the same FOC 102 or container pair.

For example, the coupling may comprise coupling the telecommunications infrastructure of the FOC 102 to each other and/or to the telecommunications module 202t, coupling the temperature control infrastructure of the FOC 102 to each other and/or to the temperature control module 202k, and/or coupling the power supply infrastructure 106 of the FOC 102 to each other and/or to the power module 202z.

In the following, reference may be made more generally to an infrastructure of the FOC 102 for ease of understanding, and what is described for the infrastructure may apply to the power supply infrastructure 106, the temperature control infrastructure, and/or the telecommunications infrastructure (e.g., by analogy). More generally, coupling of an infrastructure may be accomplished by means of a coupling interface 722 to which the infrastructure has corresponding connections. For example, the infrastructure of an FOC 102 may be coupled to the supply module assembly 202 by means of a feed interface (more generally, a first coupling interface) or to an immediately adjacent FOC 102 by means of a container-to-container interface (more generally, a second coupling interface).

For example, the infrastructure (e.g., the telecommunications infrastructure, power supply infrastructure, and/or temperature control infrastructure) may have a plurality of first supply lines that couple the feed interface to the computing device or a terminal device (e.g., a heat exchanger) of the infrastructure. Alternatively or additionally, the infrastructure may have multiple second supply lines coupling the container-to-container interface (CC interface) to the computing device and/or the feed interface.

For example, the telecommunications infrastructure has a plurality of network lines coupling the coupling interface to the computing device for connecting the plurality of processors to a local and/or global network (e.g., the Internet). For example, the temperature control infrastructure has a plurality of fluid lines (e.g., pipes for flow and return) coupling the coupling interface(s) to the computing device so that thermal energy may be extracted from the computing device.

For example, the supply lines may be arranged in trays (e.g., hanging cable trays) on the ceiling and/or floor of the FOC 102 and spaced from the loose walls 102s. For example, a raised floor may be used to route the utility cables. The coupling interface(s) 722 may be attached to partition walls, for example, and spaced from the loose walls 102s. This may be used to ensure that pre-certification is not lost by opening the loose walls 102s. To provide electrical power for operation of the computing device 104 of the FOC 102, each (e.g., the first and/or the second) coupling interface 722 may be configured to provide the electrical power or a double thereof, e.g., a power of, for example, more than about 100 kW, than about 150 kW, than about 200 kW, than about 250 kW, or than about 500 kW (kilowatts).

In various embodiments, the computing device comprises a plurality of computing units, each computing unit comprising at least one receiving device (e.g., comprising a rack, such as a 19-inch rack or a 21-inch rack) for receiving processors. Such receiving device(s) may be, for example, racks for receiving processor cards and/or entire servers (referred to as “rigs”). The or each computing unit may optionally include a cooling device for cooling the processors (i.e., extracting thermal energy), e.g., a passive cooler and/or a heat exchanger.

FIG. 2 illustrates a supply chain 200 according to various embodiments in a schematic supply diagram showing a power flow diagram with various technology attachment containers. A computing center may include one or more than one supply chain 200, each supply chain 200 of which may include a supply module assembly 202 (e.g., including a supply container and/or technology container, and optionally including an electrical container and/or hydraulic container) and at least one FOC 102 of the computing center module 151.

For example, the supply module assembly 202 may include an airlock module 212 (e.g., a spatially separated airlock). The telecommunications module 202t may include, for example, two telecommunications ports 214 that are redundant with respect to each other. Accordingly, the telecommunications infrastructure (also referred to as TK infrastructure) may include at least two redundant telecommunications supply paths, each telecommunications supply path of which may be or may be coupled to one of the telecommunications ports 214. The telecommunications infrastructure or a telecommunications path may alternatively or additionally be path-redundantly coupled to the telecommunications ports 214 on the opposite side of the container.

For example, the power module 202z may include a low-voltage main distribution 218 and two uninterruptible power supplies 216 (UPS) coupled thereto and redundant with respect to each other, each UPS 216 of which may be rated at, for example, 250 kW (kilowatts) or more. The low-voltage main distribution 218 may be coupled to a regional interconnected grid 218v, for example. The power module 202z may include, for example, one or more than one power generator 220, such as an emergency power generator. For example, the power generator 220 may include an internal combustion engine (e.g., diesel engine). The power generator may be powered by, for example, a diesel tank 221 for 72 or 96 hours. Accordingly, the power supply infrastructure 106 may include at least two mutually redundant power supply paths, each power supply path of which may be or may be coupled to one of the UPS 216. For example, each power supply path may include one or more than one sub-distribution device 106u (also referred to as UV), each UV 106u of which may be or may become coupled to one of the plurality of UPS 216. This may provide redundant supplied electrical power, with each supply path being able to compensate for the failure of another supply path. For example, a first UV 106u may include a first power line 1061 and a second UV 106u may include a second power line 914, wherein the first and second power lines are arranged to supply power to the same processor. Optionally, the power supply infrastructure may include a base power distribution 106n separate from the computing device 104, which supplies power to components of the FOC 102 not associated with the computing device 104, for example (e.g., lighting, ventilation, cooling), i.e., illustratively provides a base power supply.

The temperature control module 202k (here exemplarily arranged together with the energy module 202z in a technology container) of the supply module assembly 202 may be arranged to extract thermal energy from the interior of the FOC 102 (e.g., the computing device 104), for example by means of a cooling fluid (e.g., a liquid). For example, the temperature control module 202k may include one or more heat pumps 222, which may be set up to be redundant to each other, for example. For example, the temperature control module 202k may provide one or more than one cooling circuit 224 (e.g., having different temperature levels of cooling water/hot water and respective supply and return lines) with the FOC 102. To this end, the temperature control infrastructure 114 of the FOC 102 may include one or more than one fluid line 1141 coupled to one or more than one processor cooler 104w of the computing device 104. The or each processor cooler 104w may be configured to extract thermal energy from the processors of the computing device 104 and supply it to the cooling circuit 224. The resulting hot water may be brought out of the FOC 102 and/or cooled using the heat pumps 222.

For example, the temperature control infrastructure of the FOC 102 may include one or more than one air handler 104l (e.g., a recirculating air cooler) coupled to a cooling fluid supply of the cooling circuit 224. The or each air conditioner 104l may be configured to extract thermal energy from (i.e., cool) the air within the FOC 102 and/or supply cooled air to the computing device. At least two fluid lines 1141 and/or air conditioners 104l may optionally be set up to be redundant to each other. For example, the cooling circuit 224 may be cooled and/or supplied by means of a cooling tower, by means of a body of water (e.g., river water and/or lake water), by means of local cooling, by means of district cooling, by means of a chiller, and/or by means of a heat pump 222.

The supply module assembly 202 may optionally include an emergency module 242 that may, for example, supply one or more than one fire extinguishing device 242l of the FOC 102 (e.g., comprising an extinguishing gas supply). At least two fire extinguishing devices 242l (more generally, fire extinguishing infrastructure 242l) of the FOC 102 may optionally be redundant to each other. One fire extinguishing device 242l may supply (for example, exactly) one or two FOC 102, which may be interconnected by means of the lines 242l. Necessary overpressure openings may be arranged on the face side next to the doors of the airlock 212 close to the ceiling above the normal power distribution 106 and optionally extended to the outside by means of a duct above the medium voltage distribution 218.

Each supply path of one or more than one infrastructures, such as power infrastructure 106, temperature control infrastructure 114, telecommunications infrastructure 214 and/or firefighting infrastructure 242l may have at least one corresponding pair of mutually redundant connections and/or a pair of supply and return lines at the feed interface 412.

The feed interfaces 412, 722, may be standardized connections, e.g., flanged connections, commercially available plug-in connections, or otherwise.

FIG. 3 illustrates a supply chain 300 according to various embodiments in a schematic supply diagram showing a power flow diagram with various technology attachment containers, e.g., supply chain 200.

The supply module assembly 202 of the supply chain 300 may include a ventilation module 302. The FOC 102 may include an air intake opening 302a (e.g., warm air exhaust) and an air output opening 302z (e.g., cold air supply) that may be or may be coupled to the ventilation module 302. The ventilation module 302 may further provide an air duct system 302l that interconnects with one another the air intake opening 302a and the air discharge opening 302z, as well as the outside air opening 302o and the exhaust air opening 302f.

The air duct system 302l may include a recirculation bypass 302u and a heat removal bypass 302v. By means of open air dampers 312v and closed dampers 312w, recirculation mode may be run via the recirculation bypass 302u. By means of closed air dampers 312v and open dampers 312w, it is possible to run in outdoor air mode (also referred to as free cooling). With partially open air dampers 312v and 312w, the supply air 302z (free cooling) may be increased to a minimum temperature level in outdoor air mode by means of a partial volume flow via the recirculation air bypass 302u (supply air temperature control). The air duct system 302l may include at least one fan 302p configured to draw air from the FOC 102 by means of the air intake opening 302a (warm air exhaust), pass the air over a heat exchanger 302k (e.g., cool it by means of the heat exchanger), and supply the air by means of the air delivery opening 302z (e.g., cold air supply) (also referred to as recirculation operation). The fan 302p may also perform a function of conveying cold air via the outdoor air opening 302o through the supply air opening 302z (also referred to as free cooling). The fan 302k may also perform a function of maintaining the FOC 102 at a positive pressure to prevent or minimize dust or smoke ingress, such as when doors are opened.

An air filter 312f may be arranged as close as possible to the outside air opening 302o to filter the outside air or additionally the recirculated air and to keep the FOC 102, the duct system 302l and its components 302p, 302k and optionally the components 312p, 202e as dust-free as possible.

The ventilation module 302 may further include a heat pump 222 with its fluid lines 2221 and one or more heat exchangers 302k for the side to be cooled and 302e for the heat output. The heat pump(s) or chiller(s) are powered by, for example, normal current 106n.

Alternatively, the heat exchanger 302k may be cooled by means of a body of water (e.g., river/lake water), by means of local cooling, by means of remote cooling, by means of a chiller 302w, and/or by means of the heat removal pipe system 224.

The ventilation module 302 may further include a heat dissipation arrangement 302v configured to dissipate thermal energy to the outside and to avoid attachments outside the container 302. The heat dissipation arrangement 302v may include a heat exchanger 302e coupled to the heat pump 222 via the piping system 2221. The heat dissipation arrangement 302v may further comprise an additional fan 312p, which is arranged to pass colder outside air 302o through the heat removal bypass 302v and over the heat exchanger 302e, and to discharge heated air to the outside air via an exhaust air grille 302f. In this case, the air flow is directed through the open air dampers 312v and blocked by the closed dampers 312w.

For example, the ventilation module 302 has an air flow rate in the range of 1000 to 11000 m³/h (cubic meters per hour) at a compression of 50 to 200 Pa (Pascal), for example, an air flow rate in the range of 9000 to 11000 m³/h at a compression of 75 to 175 Pa, or for example, an air flow rate in the range of 9800 to 10200 m³/h at a compression of 100 to 150 Pa.

For example, the heat exchanger 202k may have an output of 90 kW or more, and the heat pump may have a rated heat output of 120 kW or more.

FIG. 4 illustrates a computing center module 151 according to various embodiments in a schematic supply diagram 400. The computing center module 151 may include two FOC 102 (also referred to as a pair of containers) coupled to each other by means of their CC interfaces 402. The computing center module 151 (e.g., each FOC 102 thereof) may optionally be coupled to a supply module assembly 202 by means of its feed interface(s) 412, e.g., according to supply chain 200 or 300.

Each FOC 102 of the pair of containers may have the feed interface 412 opposite the CC interface 402, which may optionally be coupled to the supply module assembly 202 associated with the FOC 102 or coupled to one or more of the central supply systems 202z, 202k, 202f. The CC interface 402 may be configured to couple the supply lines of the infrastructures (e.g., the power supply infrastructure, the telecommunications infrastructure, and/or the temperature control or gas extinguishing infrastructure) of the two FOC 102. For example, the infrastructures of the two FOC 102 may be set up mirror-symmetrically with respect to each other for this purpose, e.g., their CC interface 402 and/or supply lines.

The CC interface 402 allows the components of the supply module assembly 202 that are redundant to each other for one FOC 102 to be used for two FOCs 102. For example, one or more than a first port 202a of the feed interface 412 (also referred to as the first feed port 202a) of the first FOC 102 may be or may be coupled to a second FOC 102 by means of the CC interface 402 thereof. Alternatively or additionally, one or more than one second feed port 202b of the second FOC 102 may be or become coupled to the first FOC 102 via its CC interface 402. A plurality of first feed ports 202a and/or a plurality of second feed ports may be arranged redundantly with respect to each other and/or on opposite sides of the feed interface 412. Each first and/or second feed port 202b may be configured to supply power, telecommunications, and/or extinguishing gas, for example.

FIG. 5 illustrates a computing center module 151 according to various embodiments in a schematic supply diagram 500. The computing center module 151, its FOC 102, may be coupled to multiple supply module assemblies 202, e.g., according to supply chain 200 or 300.

Each FOC 102 may include three contiguous loose walls 102s. To form the computing center module 151, the loose walls 102s of each FOC 102 may be opened (e.g., disassembled) and the adjacent FOC 102s may be physically connected to each other using an expansion joint. In other words, a loose wall 102s may include a demountable or pivotable supported wall element (illustratively, a large door). However, the loose walls 102s may be configured in other ways. For example, a loose wall 102s may include a folding door (also referred to as a folding wall).

Thus, a first loose wall 102s and a second loose wall 102s of each FOC 102 facing another FOC 102 may be or may become open. The first loose wall 102s may be opened to expose the front-facing CC interface 402. A third loose wall 102s may be opened to expose the front-facing feed interface 412. Optionally, the feed interface 412 and the CC interface 402 may be arranged and implemented in the same or mirrored manner (e.g., same diameters and spacing).

For example, the fourth sidewall 112s (also referred to as the fixed wall 112s) may be monolithically configured and/or materially bonded to or part of the housing structure of the FOC 102.

Along the longitudinal extent of each FOC 102 (i.e., on the longitudinal sides thereof), the FOC 102 may include two aisles 102g, 112g between which the computing device 104 is disposed and each of which is disposed between the computing device 104 and a side wall of the FOC 102 (e.g., spatially separating the side walls). A first aisle 112g adjacent to the second loose wall 102s may be narrower than a second aisle 112g adjacent to the fixed wall 112s. In other words, the computing device 104 may be disposed closer to the second loose wall 102s than to the fixed wall 112s.

This allows a wider computing device 104 to be installed without making the aisle width too narrow. Illustratively, the second aisles 112g of the FOC 102 may be contiguous and thus connected to each other (to form a center aisle 112g, 112g) by means of the opened second loose wall 102s so that sufficient aisle width is provided. For example, the width of the center aisle may satisfy a pre-certification requirement or accommodate a customer request for sufficient maintenance space. Alternatively or additionally, the aisle width of each second aisle 112g may be less than 0.7 m (meters) and/or greater than 0.3 m. Alternatively or additionally, the aisle width of each first aisle 102g may be greater than 0.7 m (meters).

The gas extinguishing interface 242l may be used to efficiently supply the room network of two FOC 102 set up next to each other from (e.g., exactly) one gas extinguishing control center 202f or one gas cylinder system 242 or one control system in accordance with the standards.

More than two FOC 102 may be arranged horizontally side-by-side as shown in supply diagram 500. Alternatively, or additionally, more than two FOC 102 may be arranged on top of each other (e.g., stacked).

The pair of FOC 102 coupled together by means of the CC interface 402 may be designated as a first type container pair. Two first type container pairs may each form the center aisle 112g, 112g. Alternatively, or in addition to a first type container pair, an FOC 102 may be used that includes two computing devices and infrastructures that are mirrored symmetrically to each other (such that the CC interface 402 is omitted).

In other words, an FOC 102 may stand alone and/or be connected at the short end(s) to a supply module 202 (e.g., comprising a technology container, an electrical container, and/or a hydraulic container) and optionally to a ventilation container 302 (cf. FIGS. 2 and 3).

In an additional deployment configuration, two FOCs 102 (e.g., two 20 ft containers) may be combined with the short end face to form a composite (e.g., a 40 ft variant) (also referred to as a longitudinal composite). Alternatively, or in addition to the longitudinal composite of two FOCs 102, a larger one (e.g., a 40 ft container) may be used, which allows the interface 402 (FIG. 4) between the two FOCs 102 to be unnecessary.

But also two FOCs 102 may be combined (also referred to as a wide composite) via the long loose wall 102s to create a wider rear or center maintenance aisle without having to create a longitudinal grouping (e.g., a 40 ft grouping) via the interface 402 (see FIG. 5, upper wide grouping or lower wide grouping of computing center module 151, respectively). However, a large wide grouping (general room grouping) may also be established using four FOCs 102 (FIG. 5), for example, two FOCs 102 each of which are provided as a longitudinal interconnect.

Alternatively or additionally, a vertical combination/extension may be made until, for example, a maximum of 6 FOCs 102 are arranged one above the other.

The basis of all set-up configurations may be the same or a symmetrically constructed platform of the FOC 102, which may be merely mirror symmetrical with respect to the outer walls 102s of the FOC 102.

An FOC 102 as an IT container may be connected individually or in a grouping optionally with one or more technology containers and/or one or more electrical containers, hydraulic containers or fire-fighting containers and other infrastructure components such as generators directly or indirectly to form a computing center.

FIG. 6 illustrates a computing center 600 according to various embodiments in a schematic supply diagram. Multiple computing center modules 151 of computing center 600 may be arranged horizontally side-by-side as shown in supply diagram. Alternatively or additionally, multiple computing center modules 151 of computing center 600 may be arranged on top of each other (e.g., stacked).

Each container pair 602 of each computing center module 151 may be coupled to two supply module assemblies 202, e.g., according to supply chain 200 or 300. The two supply module assemblies 202 may be redundant to each other and/or each may be coupled to two container pairs 602 (e.g., using separate supply lines 642).

The computing center may include a medium voltage main distribution 604 coupled to each supply module assembly 202. Each supply module assembly 202 may optionally be coupled to a fuel supply 606 (e.g., supplying gas or diesel). Each supply module assembly 202 may include a plurality of modularly-provided supply devices (then also referred to as modules), e.g., a transformer 612, a power generator 220, a low voltage main distribution 218, a UPS 216, a normal power distribution 616, a cold water supply 618 (e.g., chilled water generation 618), a cooling tower 620, a heat pump system 222, and/or an emergency module 242 (e.g., including a firefighting gas reservoir).

In various embodiments, the heat pumps 222 of the supply module assembly 202 are high temperature heat pumps. Depending on the heat pump, heat may then be extracted from the FOC 102 from a temperature level of, for example, at least 30° C., for example, at least 40° C., for example, at least 50° C., for example, at least 60° C., and this heat may be raised to a higher temperature level of, for example, at least 50° C., for example, at least 60° C., for example, at least 70° C. or 85° C.

Alternatively, or in addition to the chiller 618, a district cooling connection 618f may be provided. In addition to the heat pump system 222 in conjunction with the cooling tower 620, a district or local heat line 222f may be connected to put the waste heat to use.

FIG. 7 illustrates a pre-certified FOC 102 according to various embodiments in a schematic body diagram 700. The FOC 102 may include at least three loose walls 102s in its housing structure 1102g, optionally a fixed wall 112s, and one or more than one infrastructure 702 (e.g., the power supply infrastructure 106, the temperature control infrastructure, and/or the telecommunications infrastructure). For example, the fixed wall 112s may extend along a longitudinal extent of the FOC 102 and/or may be disposed on a longitudinal side of the FOC 102. The fixed wall 112s and the second loose wall 102s (also referred to as longitudinal side walls) may be disposed opposite each other. Further, the first loose wall 102s and the third loose wall 102s (also referred to as front side loose walls) may be arranged opposite each other.

An intermediate wall 102z (e.g., fixed between the housing structure) may be disposed between each of the computing device 104 and the first loose wall 102s and the third loose wall 102s. The computing device 104 and/or the supply lines 702l of the infrastructure 702 may be disposed between the two intermediate walls 102z. Each intermediate wall 102z may optionally include a door opening 712 in which, for example, a door 712t (also referred to as a personnel door 712t) may be disposed. The door opening 712 may have a width of, for example, less than half the internal dimension of the FOC 102 and/or as about 1.5 m, for example as about 1 m. The personnel door 712t may be a security door. The security door 712t may be configured to be lockable and/or fireproof and/or smokeproof. For example, the security door 712t may provide access control.

Further, the infrastructure 702 may include at least one pair (e.g., two pairs) of mutually redundant supply paths 702u, each pair of which couples the feed interface 412 to the computing device 104. For example, each computing unit 104a, 104b of computing device 104 may be coupled to a pair of mutually redundant supply paths 702u. To this end, the computing unit 104a, 104b may be configured, for example, to switch between a pair of mutually redundant infrastructure couplings 704n (e.g., per computing unit 104a, 104b) of the computing device 104. Alternatively or additionally, the infrastructure 702 may be arranged to switch between the mutually redundant supply paths 702 of a pair. The switching may be performed, for example, by means of an automatic transfer switch. The infrastructure coupling may be arranged to couple the infrastructure to the computing device 104. For example, the infrastructure coupling may be a power supply or a telecommunications device of the computing device 104.

For example, the feed interface 412 may include at least a pair of mutually redundant feed ports 412a, 412b, of which a first feed port 412a is coupled to the computing device 104 (e.g., each computing unit 104a, 104b) by at least a first supply line 702l, and a second feed port 412b is coupled to the computing device 104 (e.g., each computing unit 104a, 104b) by at least a second supply line 702l. Each of the supply paths may include, for example, a plurality of supply lines and/or a distribution unit that couples the plurality of supply lines to the feed interface 412.

Optionally, the infrastructure 702 may couple the feed interface 412 to the CC interface 402. For example, the CC interface 402 may include mutually redundant CC ports 402a, 402b, at least a first CC port 402a of which is coupled to the at least one first feed port 412a, and at least a second CC port 402b of which is coupled to the at least one second feed port 412b. The CC interface 402 and/or the feed interface 412 may each be located on different intermediate walls 102z.

Optionally, an additional intermediate wall 102z may be disposed on the fixed wall 112s, and may support one or more than one component of the FOC 102, e.g., the infrastructure 702, a user interface, or the like. The additional partition 102z allows the fixed wall 112s to remain unchanged and/or provides additional thermal insulation to the FOC 102.

For example, the pre-certified FOC 102 may be transported internationally via the established container distribution channels of truck, barge, ocean-going container ship. The FOC may be unaltered externally to retain the international CSC certificate or other transport certificate (e.g., for international transport) and/or to look as inconspicuous as possible. For example, all container exterior walls may be substantially fully unfinished (e.g., without holes or internals) in order to retain the CSC certification for international transport. This is made possible, for example, by means of the partition walls 102z.

For example, the FOC 102 (or computing device 104) may be set up to be highly reliable, through a redundant infrastructure 702 that meets, for example, the requirements of a European and/or international certification regarding the reliability of the computing device 104 (e.g., at least according to availability class 3). Illustratively, the FOC 102 may enable the highest possible output density with high reliability and practical interior design typical of a computing center. Further, maximum applicability may be achieved, e.g., by the FOC 102 being a standard 20 ft container, a standard 40 ft container (e.g., for scaling), or a standard 10 ft container. Optionally, by a symmetrically mirrored design of multiple FOC 102, pairing and thus increased modularity may be achieved. Alternatively or additionally, the media supply (for example energy, temperature control fluid, fresh air, communication, etc.) may be provided from the outside by means of modular supply devices, e.g. by means of front-attachable building services containers. The FOC 102 may optionally have a raised floor for electrostatic discharge and/or to accommodate the supply lines.

The FOC 102 may be designed as a container that may be opened on multiple sides (e.g., three sides), which may be fed in (e.g., has media fed in) on only one end face and/or has a personnel door on only one end face, so that a computing center that may be scaled in 4 directions (up, left, right, and toward the other end face) may be formed.

The use of the second aisle 112g on both sides (as a maintenance aisle) compensates for the narrow width of the FOC 102. This compensates for the lack of space behind the computing units 104a, 104b. One or more than one loose wall 102s may be opened, e.g., removed, if needed, e.g., an expansion with additional FOC 102.

The or each FOC 102 of the computing center module 151 may be commissioned at a site that (e.g., its supply module assembly) also meets reliability requirements (e.g., Internet speed, seismic reliability, flood reliability, power availability, etc.). For example, the site may have: two separate power feeds, two connections from different Internet service providers (e.g., fiber optics), an optional heat network to remove reused waste heat, an optional district cooling connection and/or deep water connection, an optional gas connection, an optional potable and/or waste water connection.

One or more than one medium may be provided locally by means of the supply module assembly 202, e.g., cold water (having about 18° C. and/or 24° C. and/or having a temperature difference of 6 Kelvin or more), dry cooling (e.g. by means of gas), a low voltage 400 V (alternating current—AC) generated from a medium voltage (by means of a transformer 612), an uninterruptible current (e.g., by means of UPS), an optional generator current (e.g., by means of a generator), an optional central extinguishing gas, an optional central water-to-water heat transfer.

For example, the UPS may include an electrical energy storage device (e.g., storage batteries or other batteries) configured to provide power according to the power consumption of the computing device for several minutes (e.g., about 15 minutes or more). The generator may optionally include a storage tank adapted to hold fuel (e.g., gas or diesel) according to a consumption of the generator for at least 24 hours (e.g., 72 hours or 96 hours or more). The water-to-water heat transfer may be or may be provided by means of a heat pump, e.g., a high temperature heat pump system.

The infrastructure 702 may be arranged to meet the requirements of availability class 2 or higher (e.g., availability class 3) with respect to the reliability of the computing system 104 and may be pre-certified accordingly, e.g., in accordance with Tier and/or in accordance with DIN EN 50600.

The enclosure structure (e.g., fixed wall) of the FOC 102 may be steel, which may optionally include one or more personnel doors. The enclosure structure of the FOC may include four corner steel beams and their horizontal steel connecting beams (and optionally the floor structure), which are adjacent to the partitions 102z. The enclosure structure may be configured to support the weight of the one ore more FOCs 102 (e.g., at least two or three times thereof). Thus, multiple FOCs 102 may be stacked on top of each other (e.g., up to 8 FOCs 102). Optionally, the FOC may be free of windows (e.g., glazing). Each loose wall 102s may be a non-load bearing sidewall, the removal of which does not substantially affect the load bearing capacity of the FOC 102.

The end-face intermediate walls 102z may, for example, be set up to be burglar-proof (e.g., made of metal) and optionally have lockable and/or burglar-proof doors 712t that are connected to one another by means of the first gangway 102g. The burglar-proofing of the intermediate walls 102z or at least of the personnel door(s) may, for example, meet the requirements of a resistance class (RC) according to DIN EN 1627 (of 2011), e.g., resistance class 2 (RC2) or more, e.g., resistance class 3 (RC3) or more. The end-face intermediate walls 102z may be designed as tight and pressure-resistant walls stable (e.g. with a reduced stud spacing) in such a way that an extinguishing gas system 242 or 202f causes less or no (illustratively inadmissible) deflections in the event of a triggering and/or be equipped with an overpressure flap 242k (e.g. at the top next to the door opening 712 in the dimensions 250×250 mm or smaller) which allows a safe discharge of an extinguishing gas.

The optional raised floor of the FOC 102 may serve to protect the engineering equipment, to elevate the lower edge of the door above snow level and/or flood protection. The supply lines may be arranged in the raised floor. This also increases safety. The raised floor may optionally include one or more than one fire alarm (e.g., at least two lines, for alarm externally or activation of an extinguishing gas system/triggering or extinguishing gas system) and/or an extinguishing gas outlet or pressure relief opening to the outside or within the raised floor. Optionally, the raised floor may have a connection to a smoke aspiration system or an early smoke detection system for a pre-alarm and a shutdown of all ventilation systems.

Optionally, the CC interface may be set up as a feed interface, which enables a two-sided media supply. For a two-sided media supply to the FOC 102 (e.g., with cooling fluid and/or power), there may be twice as many supply lines (e.g., twice the redundancy, e.g., 2·(N+1)), which further increases the power that may be dissipated (to e.g., 250 kW or more). Alternatively or additionally, a path redundant supply from the ice feed interface 412 and the CC interface may be enabled, e.g., with electrical power.

For example, the supply lines of the temperature control infrastructure 114 may pass completely through the FOC and/or flange covers or blind flange covers of the docking interfaces 722 at the end faces of the FOC 102. Shut-off valves at each end and/or between two computing units 104a, 104b may allow redundancy switching and/or two-sided media supply.

The power supply infrastructure 106 may include two separate UV 106u and/or cable trays separated from each other, for example, to meet availability class 2 (e.g., Tier 2) and above requirements (e.g., supplying UPS power A and B). The cable runs may be continuous throughout the FOC 102 in the raised floor to provide, for example, two supply paths away from each other from the feed interfaces 412 on opposite ends of the FOC 102 (e.g., first power supply on the left and second power supply on the right for a 40-ft FOC). Each supply path or UV 106u may be configured to provide a supply power of at least 250 kW (kilowatts) or less. For example, the cross-section of the supply lines of each supply path may be arranged to provide supply power at either 220 V (volts) or at 110 V. Alternatively, or additionally, each supply path of the power supply infrastructure 106 may be arranged to provide power of about 250 kW or more per 6 meters of longitudinal extent of the FOC 102, and/or in aggregate to provide about 500 kW or more (e.g., with less or no redundancy).

For example, the base power supply by means of the power supply infrastructure 106 does not necessarily need to be or be backed up by means of a UPS and/or may be provided by means of a backup generator. For example, the FOC 102 may be free of a heat pump and/or a UPS 216.

Each power supply path of the power supply infrastructure 106 may, for example, have multiple (e.g., four) connector strips and/or separately carry and/or protect three power phases. Each of the power strips may optionally be configured to switch, by means of an automatic transfer switch, to the other of the power supply paths in the event of a failure of one of the power supply paths. This allows components of the computing device 104 that do not have two power supplies to be provided with reliable power.

Each power supply path (e.g., its connector strip) may optionally be coupled to the telecommunication infrastructure 914 and/or implement a remote access protocol that is arranged to control and/or read out the power supply path by means of the telecommunication (e.g., a network and/or the Internet). For example, this may allow temperature and/or power to be read. The remote access protocol may alternatively or additionally implement a serial on and/or off switching of the power strips. This prevents electromagnetic fields that are too strong.

Optionally, the supply paths 702l of the or each pair of mutually redundant supply paths 702l (e.g., of the power supply infrastructure and/or the telecommunications infrastructure) may be arranged on opposite sides (e.g., the long sides) of the FOC 102 (e.g., the computing device may be arranged between them). Thus, for example, an availability class of 3 or 4 may be achieved.

Optionally, the FOC 102 may be configured to provide a mirroring of the data from the computing device 104 to another FOC of the or another computing center module 151 using the CC interface 402.

Further, the FOC 102 may include a fire extinguishing device that satisfies the pre-certification requirements. For example, a fire extinguisher may be located in each FOC 102, which may satisfy an availability class 1, for example. For an availability class of 2 or more, a fire extinguishing device of the FOC 102 may include an early fire warning system (e.g., comprising a smoke or heat detector) and/or automatically request and/or supply an extinguishing agent (e.g., the extinguishing gas) to the interior of the FOC 102 upon detection of a fire. Optionally, the fire extinguishing device of the FOC 102 may be configured to supply an extinguishing agent (e.g., gas) in a volume predetermined in accordance with the pre-certification and/or provide extinguishment within a time predetermined in accordance with the pre-certification. For example, the early fire warning system may be arranged to draw air from the raised floor and/or the UV 106u and the computing device 104 and check for the presence of smoke particles.

FIG. 8 illustrates several availability classes according to different embodiments in a schematic diagram 800. Each of the availability classes 1 to 4 may have requirements for the infrastructure 702 (e.g., the power supply infrastructure, the temperature control infrastructure, and/or the telecommunication infrastructure) of the FOC, which are met individually by each FOC 102 of the computing center module 151, so that it may also be or become pre-certified if, for example, the corresponding structural and safety requirements are also met. Availability class x+1 may have at least the requirements of availability class x (x=1 to 3).

According to availability class 1, the power supply infrastructure may have at least one supply path (also referred to as power supply path) and the telecommunication infrastructure may have at least one supply path (also referred to as telecommunication supply path), e.g., with direct connections and without redundancies in the supply paths and their components.

According to availability class 2, the at least one power supply path may have at least one pair of mutually redundant components (e.g., power strips and/or UV), the at least one telecommunications supply path may be permanently installed, and the temperature control infrastructure may have at least one supply path (also referred to as temperature control supply path). According to availability class 2, optionally: the telecommunication supply path may have at least two telecommunication feed connections, the container floor (e.g., raised floor) may have a proof of stability (also referred to as proof of statics), the air conditioners and/or heat pumps of the temperature control infrastructure may be duplicated, the temperature control infrastructure may implement fully automatic switching to an external cold water supply (i.e., an additional cold water connection), and/or the heat exchangers for water cooling may be located outside the FOC.

According to availability class 3, optionally: the power supply infrastructure may have at least two supply paths, each supply path of which may optionally have at least one pair of mutually redundant components (or each component may be part of a pair of mutually redundant components), the telecommunication infrastructure may have multiple fixed supply paths, at least one pair of which is set up to be mutually redundant, and the temperature control supply path may have at least one pair of redundant components. According to availability class 3, optionally: each infrastructure (i.e., the power supply infrastructure, the telecommunications infrastructure, and the temperature control infrastructure) may have at least one pair of mutually redundant supply paths, the power supply infrastructure may have at least one pair of mutually redundant UV 106u, the FOC may have an early fire warning system, the FOC 102 may have a fire extinguishing device (e.g., by means of gas), at least one (e.g., each) personnel door 712t of the FOC 102 may be set up as a security door.

According to availability class 4, the power supply infrastructure may have at least two supply paths, each supply path of which is set up to be fully maintenance-tolerant, the telecommunications infrastructure may have multiple fixed supply paths, the supply lines of which are located on different sides of the FOC, and the temperature control infrastructure may have multiple supply paths, the supply lines of which are located on different sides of the FOC.

In accordance with availability class 3, the computing device may optionally include one or more than one pair of mutually redundant computing units 104a, 104b.

The requirements for the availability class(es) may be defined, for example, according to DIN EN 50600.

FIG. 9 illustrates a supply chain 900 according to various embodiments in a schematic supply diagram with schematic redundancy pairing 901. The supply chain 900 may include the supply module assembly 202 and the FOC 102. For example, the supply chain 900 may be arranged as the supply chain 200 or 300, but the FOC 102 may be or may be provided without the supply module assembly 202. The feed interface 412 may be disposed within the housing 1102g of the FOC 102 (also referred to as the container housing 1102g).

The temperature control infrastructure 114 (e.g., comprising the air conditioning 104l) may comprise at least one pair of mutually redundant supply paths, each supply path comprising a hot water and/or cold water connection 952 (e.g., flanges) at the feed interface 412. The power supply infrastructure 106 may include at least one pair of mutually redundant supply paths, each supply path of which includes at least one UV 106u and/or at least one power supply connection 916 at the feed interface 412. The telecommunications infrastructure 914 may have at least one pair of mutually redundant supply paths, each supply path having at least one network line and/or network connection at the feed interface 412 (e.g., using telecommunications interface 924s). Each computing device 104a, 104b of the computing device 104 may optionally be coupled to each pair of mutually redundant supply paths of the telecommunications infrastructure 914, the power supply infrastructure 106, and/or the temperature control infrastructure 114.

For example, this supply chain 900 may correspond to the construction of an availability class 3 computing center of which the one or more FOCs 102 are a part.

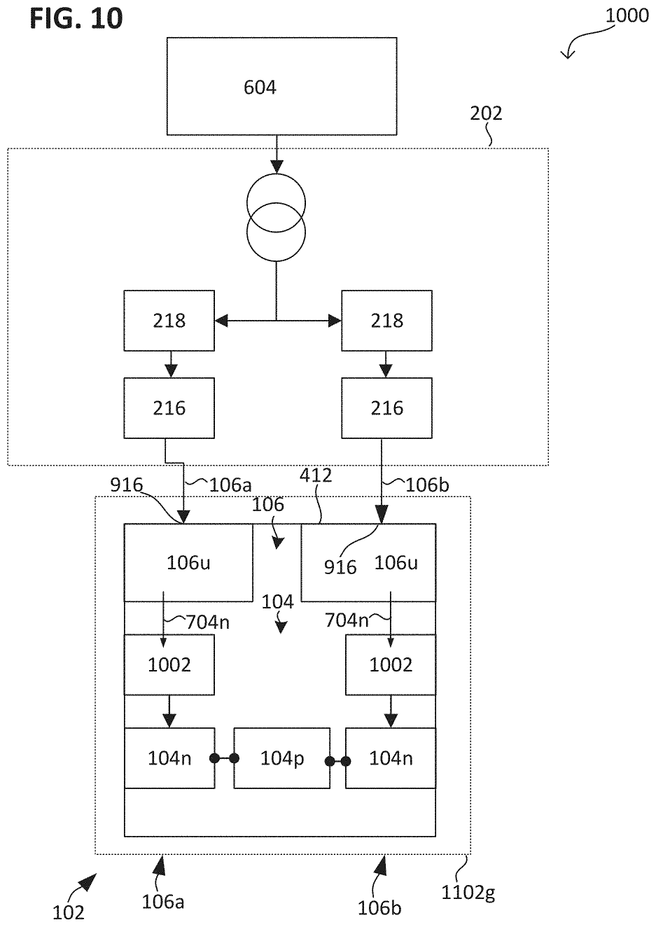

FIG. 10 illustrates a supply chain 1000 according to various embodiments in a schematic supply diagram. The supply chain 1000 may be set up, for example, like the supply chain 200, 300, or 900. The FOC 102 may also be or be provided without the supply module assembly 202.

The power supply infrastructure 106 may include at least a pair of mutually redundant power supply paths, e.g., a first power supply path 106a (also referred to as supply path A) and a mutually redundant second power supply path 106b (also referred to as supply path B), each of which power supply paths may include a UV 106u and may be coupled to a power supply 104n of the computing device. The power supplies 104n may be redundant with respect to each other and/or arranged to provide electrical power to the processors 104p (or computing devices). The or each UV 106u (also referred to as tertiary distribution device 106u or tertiary distribution) may include one or more than one protected outlet 1002 (e.g., in the form of a power strip, also referred to as a power distribution unit or PDU). Each of the power outlets 1002 may be coupled to one of two mutually redundant power supplies 104n of the computing device 104.

The tertiary distribution device 106u may be understood descriptively as horizontal distribution wiring, i.e., the distribution of supplied power within an FOC 102 (also referred to as floor wiring) to various subsystems.

For example, the power distribution in the FOC 102 (tertiary distribution) for an availability class 3 may be the same as the availability class 2 and/or the availability class 4. According to the availability class 3, the FOC 102 may have a pair of power feed terminals 916 (A and B) and/or a pair of electrical UPS 106u (tertiary distribution), each of which may be switched between (e.g., using a transfer switch).

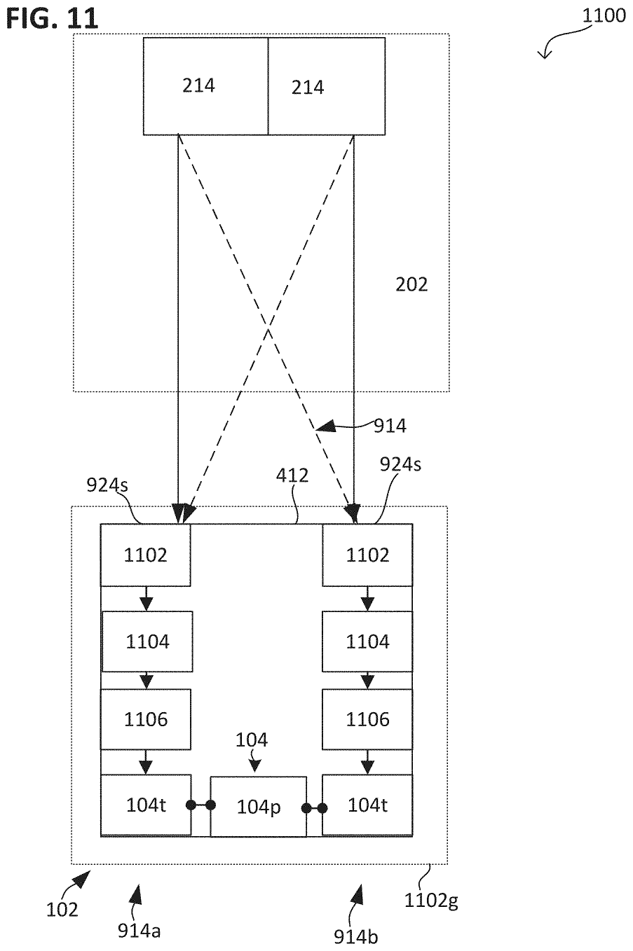

FIG. 11 illustrates a supply chain 1100 according to various embodiments in a schematic supply diagram. The supply chain 1100 may be set up, for example, like the supply chain 200, 300, 900, or 1000. The FOC 102 may also be or be provided without the supply module assembly 202.

The telecommunications infrastructure 194 may include at least one pair of mutually redundant telecommunications supply paths, for example, a first telecommunications supply path 914a and a second telecommunications supply path 914b, each of which telecommunications supply paths may include a telecommunications interface 924s and at least one telecommunications distribution. The at least one telecommunications distribution may include a main distribution 1102, an intermediate distribution 1104, and/or a zone distribution 1106.

Each of the telecommunications supply paths 914a, 914b may be coupled to one of two mutually redundant telecommunications devices 104t of the computing device 104. The mutually redundant telecommunications devices 104t may be arranged to connect the processors 104p (or computing devices) to a network and/or process messages according to a telecommunications protocol.

In the following, various examples are described that relate to what has been described above and what is shown in the figures.

Example 1 is a computing center module comprising: a plurality of containers, each container: having a plurality of sidewalls (e.g., at least one sidewall on a long side of the container and/or one sidewall on each of one or two ends of the container) that may be opened substantially (e.g. (e.g., on three sides); a computing device within the container, the computing device comprising a plurality of processors; a (illustratively reliability-enhanced) power supply infrastructure within the container for supplying the computing device with electrical power; wherein the power supply infrastructure of each container of the computing center module (e.g., individually or the entire container, respectively) is individually pre-certified with respect to a reliability of the computing device.

Example 2 is a computing center module according to example 1, wherein each container further comprises a telecommunications infrastructure for providing a telecommunications signal to the computing center, wherein the telecommunications infrastructure of each container of the computing center module is individually pre-certified with respect to a reliability of the computing center.

Example 3 is a computing center module according to one of examples 1 or 2, wherein each container comprises a temperature control infrastructure for supplying a temperature control fluid (e.g., a cooling liquid or cooled air) to the computing center module, wherein the temperature control infrastructure of each container of the computing center module is individually pre-certified with respect to a reliability of the computing center module.

Example 4 is a computing center module according to any of examples 1 to 3, wherein the or each infrastructure (e.g., the power infrastructure, the telecommunications infrastructure, and/or the temperature control infrastructure) of each container includes at least one (i.e., one or more than one) pair of supply paths.

Example 5 is a computing center module according to example 4, wherein each supply path of each pair of supply paths comprises a feed port and a supply line (e.g., power line), wherein the supply line couples the computing device to the feed port; and/or wherein the two supply paths are set up redundant to each other; and/or wherein the infrastructure comprises a transfer switch that may switch between the two supply paths to supply the computing device.

Example 6 is a computing center module according to any of examples 1 to 5, wherein the or each infrastructure (e.g., the power infrastructure, the telecommunications infrastructure, and/or the temperature control infrastructure) of each container comprises a sub-distribution device.

Example 7 is a computing center module according to any of examples 1 to 6, wherein the or each infrastructure (e.g., the power supply infrastructure, the telecommunications infrastructure, and/or the temperature control infrastructure) is at least component redundant.

Example 8 is a computing center module according to any of examples 1 to 7, wherein each container has a feed interface and a container-to-container interface which are optionally: coupled together by means of the or each infrastructure (e.g., the power supply infrastructure, the telecommunications infrastructure, and/or the temperature control infrastructure) of the container (e.g. and/or are arranged on opposite sides of the container, wherein optionally the container-to-container interfaces of adjacent containers of the computing center module face each other and/or are coupled to each other; wherein optionally the container-to-container interface and/or the feed interface of each container is exposed from an opening in a side wall of the plurality of side walls.

Example 9 is a computing center module according to example 8, wherein the container-to-container interface and/or the feed interface of each container is held by an intermediate wall disposed between one of the plurality of side walls and the computing center.

Example 10 is a computing center module according to example 9, wherein the or each partition includes a personnel door.

Example 11 is a computing center module according to any of examples 1 to 10, wherein the plurality of side walls of each container includes three side walls.

Example 12 is a computing center module according to any of examples 1 to 11, wherein at least some processors of the plurality of processors are server processors.

Example 13 is a computing center module according to any of Examples 1 to 12, wherein a power consumption for operating the computing device of each of the containers is 250 kilowatts or more; and/or wherein the power supply infrastructure is adapted to provide a power of more than twice the power consumption for operating the computing device.

Example 14 is a computing center module according to any of examples 1 to 13, wherein the computing device of each of the containers comprises at least one pair of processors redundant to each other and/or at least one pair of power supplies redundant to each other.

Example 15 is a computing center module according to any of examples 1 to 14, wherein the computing device of each of the containers comprises at least one pair of computing units redundant to each other, each computing unit comprising a plurality of processors.

Example 16 is a computing center module according to any of examples 1 to 15, wherein each of the containers is free of a heat pump.

Example 17 is a computing center module according to any of examples 1 to 16, wherein each side wall of the plurality of side walls of each container includes a form-fitted wall member, a folding wall member, and/or a wing wall member.

Example 18 is a computing center module according to any of examples 1 to 17, wherein each side wall of the plurality of side walls of each container facing another container of the plurality of containers is open.

Example 19 is a computing center module according to any of examples 1 to 18, wherein the plurality of sidewalls of each container are free of elements that affect the pre-certification, e.g., that affect the fulfillment of the requirement according to the pre-certification.

Example 20 is a computing center module according to any of examples 1 to 19, wherein the plurality of containers comprises two, four, or more containers.

Example 21 is a computing center module according to any one of examples 1 to 20, wherein each container of the plurality of containers is an ISO container; and/or wherein each container of the plurality of containers is a shipping container.

Example 22 is a computing center module according to any one of examples 1 to 21, wherein for each container: the computing device is closer to a side wall of the plurality of side walls of the container facing another container of the plurality of containers than to an additional side wall (e.g., the fixed wall) of the container, the additional side wall being opposite the side wall and optionally monolithic or non-openable (e.g., non-destructible).

Example 23 is a computing center module according to any one of examples 1 to 22, wherein the computing devices of two adjacent containers of the plurality of containers are spaced apart from each other, the spacing: satisfying a requirement of the pre-certification; and/or being greater than 0.7 m; and/or being greater than 75% of an additional distance of the computing devices from the opposite side walls of the two containers.

Example 24 is a computing center module according to any one of examples 1 to 23, wherein for each container: the computing center is elongated along a longitudinal extent of the container, and/or wherein the longitudinal extent of the computing center is less than a distance parallel thereto along which at least one side wall of the plurality of side walls may be opened.

Example 25 is a computing center module according to any of Examples 1 to 24, wherein the power supply infrastructure is set up as a power supply and power disposal infrastructure and/or is set up at least for converting the electrical energy by means of the computing system into heat and for disposing of the heat.

Example 26 is a computing center module according to any of examples 1 to 25, wherein inside the container behind at least two opposing side walls of the plurality of side walls (e.g. at the two short end walls of the container), a fixed wall being arranged in each case, the fixed wall having, for example, a feed interface (illustratively for the media to be supplied to the container, such as telecommunications, cooling liquid and/or energy) and/or at least one entrance door, so that the interior of the container remains unchanged or closed when the side walls are opened and/or when the container is coupled to the respective infrastructure.

Example 27 a method for a plurality of containers, wherein each container is arranged according to one of examples 1 to 26 and/or wherein each container comprises a plurality of side walls that may be substantially fully openable; a computing device within the container, the computing device comprising a plurality of processors; a power supply infrastructure within the container for supplying electrical power to the computing device; wherein the power supply infrastructure of each container of the computing device module is individually pre-certified with respect to reliability of the computing device, the method comprising: arranging the plurality of containers relative to each other such that each two containers of the plurality of containers are arranged immediately adjacent to each other; and for each of the containers, opening at least one (e.g., each) of the plurality of sidewalls of the container facing another container of the plurality of containers, wherein upon opening the sidewall, pre-certification of the power supply infrastructure of the container is maintained.

Example 28 is a method comprising: arranging a plurality of computing center modules according to any one of examples 1 to 26 adjacent to each other, each computing center module being arranged with respect to reliability to satisfy a requirement according to a computing center certification; arranging the computing center modules relative to each other such that respective facing sidewalls of the plurality of computing center modules may be opened along their length; and opening the facing sidewalls while maintaining compliance with the computing center certification requirement of each computing center module of the plurality of computing center modules.

Example 29 is a container, comprising: a plurality of side walls that are substantially fully openable and surround an interior of the container; a computing device within the interior of the container, the computing device comprising a plurality of processors; a power infrastructure within the interior of the container for providing electrical power to the computing device; wherein the power infrastructure of the container is pre-certified with respect to reliability of the computing device.

1-15. (canceled)

16. Computing center module, comprising:
a plurality of containers, each container
comprising a plurality of side walls that are substantially fully openable;
comprising a computing device within the container, the computing device comprising a plurality of processors;
comprising a power supply infrastructure within the container for supplying electrical power to the computing device;
wherein the power supply infrastructure of each container of the computing center module is individually pre-certified with respect to a reliability of the computing device.

17. The computing center module according to claim 16, wherein the power supply infrastructure comprises at least two supply paths.

18. A computing center module according to claim 17, wherein the power supply infrastructure comprises a transfer switch that may switch between the two supply paths to supply the computing device.

19. A computing center module according to claim 16, wherein the power supply infrastructure is at least component redundant.

20. A computing center module according to claim 16, wherein each container comprises a feed interface and a container-to-container interface coupled to each other by means of the power supply infrastructure.

21. Computing center module according to claim 20,
wherein the container-to-container interface and/or the feed interface of each container is held by an intermediate wall disposed between one of the plurality of side walls and the computing device.

22. A computing center module according to claim 21, wherein the intermediate wall comprises a door.

23. The computing center module of claim 16, wherein the plurality of sidewalls of each container comprises three sidewalls.

24. A computing center module according to claim 16, wherein each side wall of the plurality of side walls of each container comprises a form-fitted wall member.

25. A computing center module according to claim 16, wherein each side wall of the plurality of side walls of each container facing another container of the plurality of containers is open.

26. The computing center module according to claim 16, wherein the plurality of containers comprises two, four, or more containers.

27. A computing center module according to claim 16, wherein the computing device of each of the containers comprises mutually redundant processors and/or power supplies.

28. A computing center module according to claim 16, wherein each container of the plurality of containers is an ISO container.

29. A computing center module according to claim 16, wherein for each container:
the computing device is closer to a side wall of the plurality of side walls of the container facing another container of the plurality of containers than to an additional side wall of the container, the additional side wall being opposite the side wall.

30. A method for a plurality of containers, wherein each container
comprises a plurality of side walls that are substantially fully openable;
comprises a computing device within the container, the computing device comprising a plurality of processors;
comprises a power supply infrastructure within the container for supplying electrical power to the computing device;
wherein the power supply infrastructure of each container of the computing center module is individually pre-certified with respect to a reliability of the computing device, the method comprising:
arranging the plurality of containers relative to each other such that each two containers of the plurality of containers are arranged immediately adjacent to each other; and
for each of the containers, opening one of the plurality of sidewalls of the container facing another container of the plurality of containers, wherein upon opening the sidewall, the pre-certification of the power supply infrastructure of the container is maintained.
